(19) United States
(12) Patent Application Publication
(10) Pub. No.: US 2026/0107499 A1
(43) Pub. Date: Apr. 16, 2026

(54) SEMICONDUCTOR DEVICE AND METHOD OF MANUFACTURING THE SAME

(71) Applicant: TAIWAN SEMICONDUCTOR MANUFACTURING COMPANY LTD., HSINCHU (TW)

(72) Inventors: JIA-REN ZOU, HSINCHU (TW); WEI-MING LAI, TAICHUNG CITY (TW); KUO-CHANG YU, TAICHUNG CITY (TW); JYUN-JI WU, TAICHUNG CITY (TW); SYUE YI LIN, KAOHSIUNG CITY (TW); WEN-SHENG LIN, TAINAN CITY (TW)

(21) Appl. No.: 19/034,739

(22) Filed: Jan. 23, 2025

Related U.S. Application Data
(60) Provisional application No. 63/706,755, filed on Oct. 14, 2024.

(51) Int. Cl. H10D 30/65; H10D 30/01; H10D 62/10; H10D 64/27

(52) U.S. Cl. CPC H10D 30/65; H10D 30/0281; H10D 62/116; H10D 64/516; H10D 64/518

(57) ABSTRACT

A semiconductor device and method of manufacturing the same are provided. The semiconductor device includes a substrate, a gate dielectric, an isolation structure, and a gate electrode. The gate dielectric is disposed on the substrate. The isolation structure is within the substrate. The gate dielectric includes a tapered portion abutting the isolation structure. The gate electrode is disposed on the gate dielectric and the isolation structure. The tapered portion of the gate dielectric is exposed by the gate electrode.

### CROSS-REFERENCE TO RELATED APPLICATIONS

This application claims the benefit of U.S. Provisional Application No. 63/706,755, filed Oct. 14, 2024, the entire disclosure of which is incorporated by reference herein.

### BACKGROUND

The technological evolution of integrated circuit (IC) materials and design has led to smaller and more complex circuits with each generation. Throughout this evolution, functional density (i.e., the number of interconnected devices per chip area) has generally increased while geometric size (i.e., the smallest component (or line) that may be created using a fabrication process) has decreased. This scaling down results in benefits such as increased production efficiency and reduced associated costs.

The noted scaling down has further increased the complexity of IC manufacture, such that, for these advances to be fully realized, corresponding developments in IC manufacturing processes are required.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1 is a top view of a semiconductor device, in accordance with some embodiments of the present disclosure.

FIG. 2A is a cross-sectional view along line A-A′ of the semiconductor device as shown in FIG. 1, in accordance with some embodiments of the present disclosure.

FIG. 2B is a cross-sectional view along line B-B′ of the semiconductor device as shown in FIG. 1, in accordance with some embodiments of the present disclosure.

FIG. 3A is a partial enlarged view of the semiconductor device as shown in FIG. 2A, in accordance with some embodiments of the present disclosure.

FIG. 3B is a partial enlarged view of the semiconductor device as shown in FIG. 2B, in accordance with some embodiments of the present disclosure.

FIG. 3C is a partial enlarged view of the semiconductor device as shown in FIG. 2B, in accordance with some embodiments of the present disclosure.

FIG. 4A is a top view of a gate electrode, in accordance with some embodiments of the present disclosure.

FIG. 4B is a top view of a gate electrode, in accordance with some embodiments of the present disclosure.

FIG. 5A is a top view of a semiconductor device, in accordance with some embodiments of the present disclosure.

FIG. 5B is a top view of a gate electrode, in accordance with some embodiments of the present disclosure.

FIG. 5C is a top view of a gate electrode, in accordance with some embodiments of the present disclosure.

FIG. 6 is a top view of a semiconductor device, in accordance with some embodiments of the present disclosure.

FIG. 7 is a top view of a semiconductor device, in accordance with some embodiments of the present disclosure.

FIG. 8 is a top view of a semiconductor device, in accordance with some embodiments of the present disclosure.

FIG. 9 is a cross-sectional view along line C-C′ of the semiconductor device as shown in FIG. 8, in accordance with some embodiments of the present disclosure.

FIG. 10 is a top view of a semiconductor device, in accordance with some embodiments of the present disclosure.

FIG. 11 is a top view of a semiconductor device, in accordance with some embodiments of the present disclosure.

FIG. 12A is a top view of a semiconductor device, in accordance with some embodiments of the present disclosure.

FIG. 12B is a cross-sectional view along line D-D′ of the semiconductor device as shown in FIG. 12A, in accordance with some embodiments of the present disclosure.

FIG. 13A, FIG. 13B, FIG. 13C, FIG. 14A, FIG. 14B, FIG. 14C, FIG. 15A, FIG. 15B, FIG. 15C, FIG. 16A, FIG. 16B, FIG. 16C, FIG. 17A, FIG. 17B, and FIG. 17C illustrate various stages of manufacturing a semiconductor device, in accordance with some embodiments of the present disclosure.

FIG. 18 is a flowchart of a method for manufacturing a semiconductor device according to various aspects of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain error necessarily resulting from the standard deviation found in the respective testing measurements. Also, as used herein, the terms “substantially,” “approximately” and “about” generally mean within a value or range that can be contemplated by persons having ordinary skill in the art. Alternatively, the terms “substantially,” “approximately” and “about” mean within an acceptable standard error of the mean when considered by one of ordinary skill in the art. Persons having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the like thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. The term is intended to encompass numbers that are within a reasonable range including the number described, such as within +/−10% of the number described, or other values as understood by person skilled in the art. For example, the term “about 5 nm” encompasses the dimension range from 4.5 nm to 5.5 nm. Ranges can be expressed herein as from one endpoint to another endpoint or between two endpoints. All ranges disclosed herein are inclusive of the endpoints, unless specified otherwise.

The present disclosure is related to semiconductor devices and fabrication methods. More particularly, the present disclosure is related to a semiconductor device with a modified gate electrode profile, which prevents the burnout of a gate dielectric. In some cases, the isolation structure of a semiconductor device, such as a high-voltage (HV) device, may exhibit a relatively substantial thickness. This can lead to a deformed profile of the gate dielectric, particularly at the corners of the oxide-definition (OD) region. Such deformations in the gate dielectric profile are susceptible to burnout at the corners, which can adversely affect the overall performance of the semiconductor device. The embodiments of the present disclosure provide a modified profile of a gate electrode to address the aforementioned issues without the need for additional manufacturing process steps.

Transistors formed using a replacement gate (or “gate-last”) process and the methods of forming the same are provided in accordance with various exemplary embodiments. The intermediate stages of forming the transistors are illustrated in accordance with some embodiments. Some variations of some embodiments are discussed. In the illustrated exemplary embodiments, the formation of planar transistors is used as an example to explain the concept of the present disclosure. Fin field-effect transistors (FinFETs), Gate-all-around (GAA) transistors, or (CFETs) may also adopt the embodiments of the present disclosure.

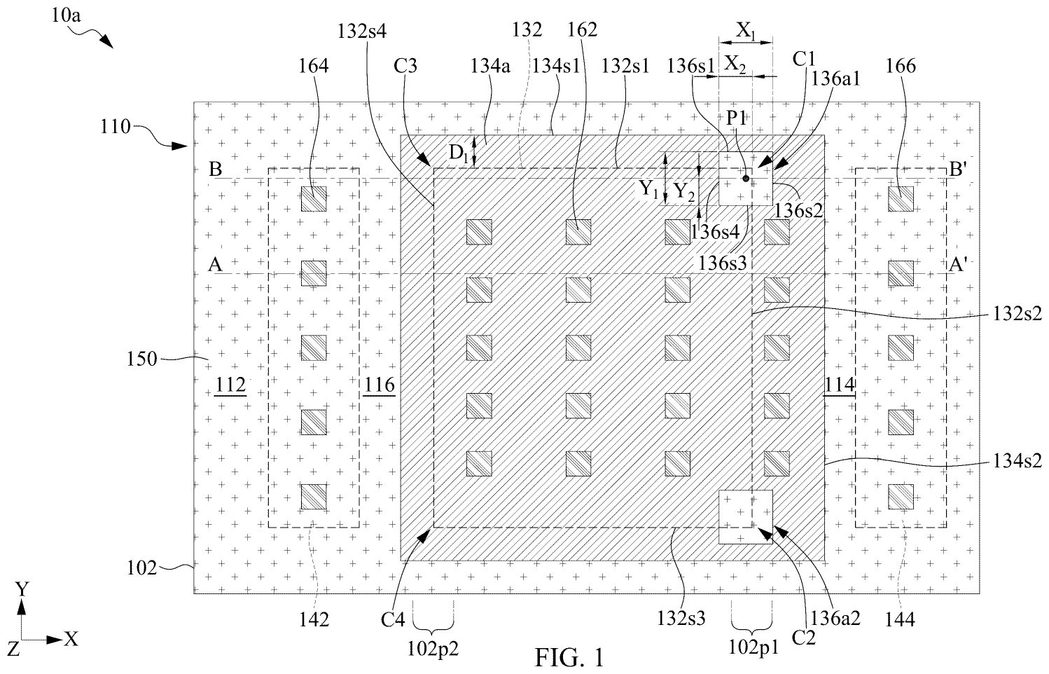

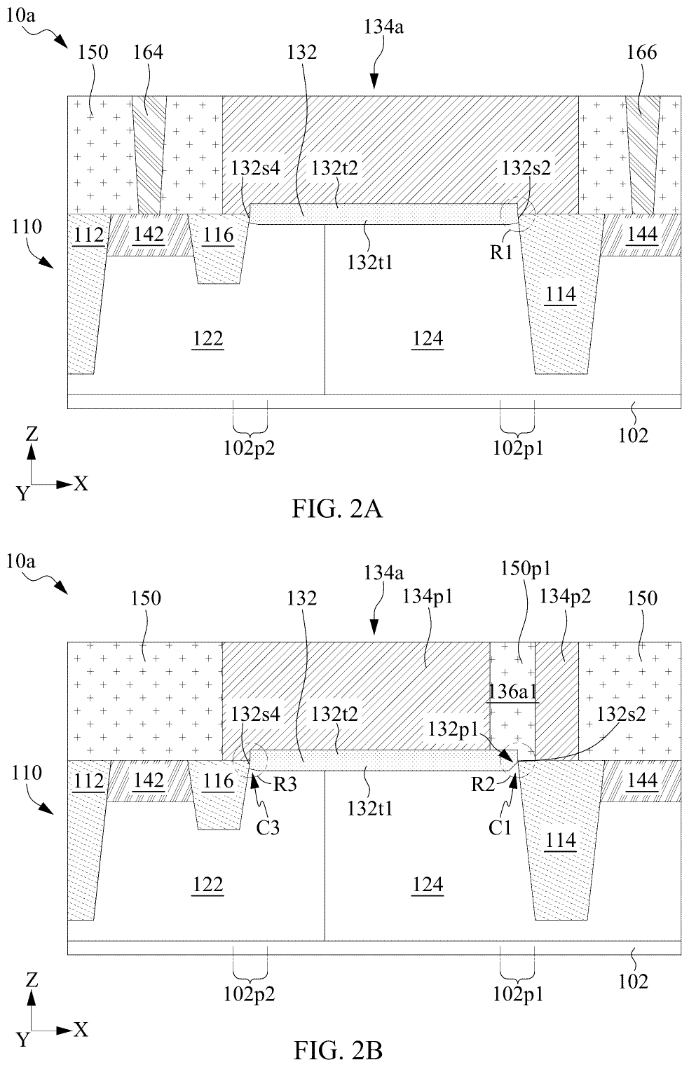

FIGS. 1, 2A, and 2B illustrate a semiconductor device 10a in accordance with some embodiments of the present disclosure. FIG. 1 is a top view of a semiconductor device 10a, and FIGS. 2A and 2B are cross-sectional views along lines A-A′ and B-B′ of FIG. 1A, respectively.

Referring to FIG. 1, the semiconductor device 10a includes a substrate 102, an isolation structure 110, a gate electrode 134a, source/drain (S/D) regions 142 and 144, and an interlayer dielectric (ILD) 150. Regions enclosed by dashed-lines as shown in FIG. 1 indicate the OD regions of the semiconductor device 10a. Some of them are configured to function as S/D features (e.g., S/D regions 142 and 144), and the remaining one, located between the S/D regions 142 and 144, can function as at least a part of the channel or indicate a region on which a gate dielectric 132 is disposed. The isolation structure 110 has multiple regions (or portions) configured to separate said OD regions. For example, the isolation structure 110 has isolation layers 112, 114, and 116. The isolation layer 114 is disposed between the gate dielectric 132 and the S/D region 144, and the isolation layer 116 is disposed between the gate dielectric 132 and the S/D region 142. The semiconductor device 10a further includes contacts 162, 164, and 166 over the gate electrode 134a, the S/D regions 142, and 144, respectively.

The gate dielectric 132 has sides 132s1, 132s2, 132s3, and 132s4 (or lateral surfaces or edges). The sides 132s1 and 132s3 extend along the X direction. The side 132s2 extends between the sides 132s1 and 132s3 and extends along the Y direction. The side 132s2 abuts or faces the S/D region 144. The side 132s4 extends between the sides 132s1 and 132s3 and extends along the Y direction. The side 132s4 abuts or faces the S/D region 142. The gate dielectric 132 defines corners C1, C2, C3, and C4. The corner C1 is defined by the sides 132s1 and 132s2. The corner C2 is defined by the sides 132s3 and 132s3. The corner C3 is defined by the sides 132s1 and 132s4. The corner C4 is defined by the sides 132s3 and 132s4. The corner C1, C2, C3, or C4 may also correspond to corners of the isolation structure 110 where the isolation structure 110 encloses the gate dielectric 132. In some embodiments, the term “corner” in the present disclosure may indicate a joint between abutting sides or indicate a region abutting said joint. For example, the corner C1 may indicate the joint between the sides 132s1 and 132s2 or indicate the region abutting the joint between the sides 132s1 and 132s2.

The gate electrode 134a has sides 134s1 and 134s2 (or lateral surfaces or edges). The side 134s1 extends along the X direction. The side 134s2 extends along the Y direction and abuts the S/D region 144.

Referring to FIG. 2A, the substrate 102 may be a semiconductor substrate, such as a bulk semiconductor, a semiconductor-on-insulator (SOI) substrate, or the like, which may be doped (e.g., with a p type or an n type dopant) or undoped. The substrate 102 can include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, GaInP, and GaInAsP; any other suitable material; or a combination thereof. In some embodiments, the alloy semiconductor substrate may be a SiGe alloy with a gradient Ge feature in which the Si and Ge composition changes from one ratio at one location to another ratio at another location of the gradient SiGe feature. In another embodiment, the SiGe alloy is formed over a silicon substrate. In some embodiments, a SiGe alloy can be mechanically strained by another material in contact with the SiGe alloy. In some embodiments, the substrate 102 may have a multilayer structure, or the substrate 102 may include a multilayer compound semiconductor structure.

The isolation layers 112, 114, and 116 are disposed within the substrate 102 and spaced apart from each other. In some embodiments, each of the isolation layers 112, 114, and 116 is a shallow trench isolation (STI). In other embodiments, the isolation layers 112, 114, and 116 may include a structure of a local oxidization of silicon (LOCOS) structure, or any other suitable isolation structure. In some embodiments, the isolation layers 112 and 116 have different thicknesses (or depths) along the Z direction. For example, the ratio of the thickness of the isolation layer 112 to that of the isolation layer 116 ranges from 2 to 20, such as 2, 3, 5, 7, 10, or 20. In some embodiments, the thickness of the isolation layer 112 is similar to or substantially the same as that of the isolation layer 114. In some embodiments, the thickness of the isolation layer 112 (or isolation layer 114) has a thickness greater than or equal to 1500 Å to facilitate a high voltage (e.g., a voltage greater than 10V or more) imposed on the semiconductor device 10a.

The substrate 102 has well regions 122 and 124. The well region 122 is disposed under the isolation layer 112, isolation layer 116, S/D region 142, and a portion of the gate dielectric 132. The well region 122 has a first conductive type (e.g., p-type). The well region 124 is disposed under the isolation layer 114, S/D region 144, and a portion of the gate dielectric 132. The well region 124 has a second conductive type (e.g., n-type) different from the first conductive type. Each of the well regions 122 and 124 includes p-type or n-type dopants therein. In some embodiments, n-type dopants include arsenic (As), phosphorus (P), other group V elements, or any combination thereof. In some embodiments, p-type dopants include boron (B), other group III elements, or any combination thereof. In some embodiments, each of the well regions 122 and 124 can be referred to as a high-voltage p-type well (HVPW) or a high-voltage n-type well (HVNW).

In some embodiments, the gate dielectric 132 is disposed on the substrate 102. The gate dielectric 132 extends between the isolation layers 114 and 116. In some embodiments, the gate dielectric 132 has two portions formed by two or more steps (or processes). For example, the gate dielectric 132 has a portion 132t1 (or lower portion) formed by a thermal technique (e.g., thermal oxidation) and a portion 132t2 (or upper portion) formed by a deposition technique (e.g., chemical vapor deposition). The portion 132t1 is at least partially surrounded by the isolation structure 110. The portion 132t2 is disposed over the portion 132t1 and is higher than the upper surface of the isolation structure 110. In some embodiments, the ratio of the thickness of the portion 132t1 to that of the portion 132t2 ranges from 0.3 to 3, such as 0.3, 0.5, 1, 2, or 3.

In some embodiments, the gate dielectric 132 includes one or more suitable dielectric materials such as silicon oxide (SiO₂), silicon nitride (Si₃N₄), silicon oxynitride (SiON), low-k dielectrics such as carbon doped oxides, extremely low-k dielectrics such as porous carbon doped silicon dioxide, a polymer such as polyimide, the like, or a combination thereof. In other embodiments, the gate dielectric 132 includes dielectric materials having a high dielectric constant (k value), for example, greater than 3.9. The materials may include metal oxides such as HfO₂, HfZrOₓ, HfSiOₓ, HfTiOₓ, HfAlOₓ, TiN, the like, or a combination thereof.

The gate electrode 134a is disposed on the gate dielectric 132. In some embodiments, the gate electrode 134a is disposed on a portion of the isolation layer 114 or overlaps the isolation layer 114 along the Z direction. In some embodiments, the gate electrode 134a is disposed on a portion of the isolation layer 116 or overlaps the isolation layer 116 along the Z direction. In some embodiments, the gate electrode 134a extends beyond the boundary (or edge) of the gate dielectric 132 and has a greater area (e.g., surface area from a top view), which improves the threshold voltage of the semiconductor device 10a.

In some embodiments, the gate electrode 134a includes at least one metallic material including elements and compounds such as molybdenum, copper, tungsten, titanium, tantalum, titanium nitride, tantalum nitride, nickel silicide, cobalt silicide, or other suitable conductive materials known in the art. In some embodiments, the gate electrode 134a includes a work function metal layer that provides a metal gate with an n-type metal work function or a p-type metal work function. The p-type metal work function materials include materials such as ruthenium, palladium, platinum, cobalt, nickel, conductive metal oxide, or other suitable materials. The n-type metal work function materials include materials such as hafnium zirconium, titanium, tantalum, aluminum, metal carbides (e.g., hafnium carbide, zirconium carbide, titanium carbide, and aluminum carbide), aluminides, or other suitable materials. In other embodiments, the gate electrode 134a includes polysilicon, silicon-germanium, or other semiconductor materials.

The S/D regions 142 and 144 are disposed on opposite sides of the gate dielectric 132 (or gate electrode 134a). The S/D region 142 is disposed between the isolation layers 112 and 116. The S/D region 142 is spaced apart from the gate dielectric 132 by the isolation layer 116. The S/D region 144 is spaced apart from the gate dielectric 132 by the isolation layer 114.

The ILD 150 is disposed on the substrate 102. The ILD 150 covers the isolation structure 110. The ILD 150 covers the gate electrode 134a. The ILD 150 includes silicon oxide, carbon-containing oxide such as silicon oxycarbide (SiOC), silicate glass, tetraethylorthosilicate (TEOS) oxide, undoped silicate glass, or doped silicon oxide such as borophosphosilicate glass (BPSG), fluorine-doped silica glass (FSG), phosphosilicate glass (PSG), boron doped silicon glass (BSG), combinations thereof and/or other suitable dielectric materials. In some embodiments, the ILD 150 may include low-k dielectric material with a dielectric constant lower than 4, or extreme low-k (ELK) dielectric material with a dielectric constant lower than 2.5. In some embodiments, the low-k material includes a polymer based material, such as benzocyclobutene (BCB); or a silicon dioxide based material, such as hydrogen silsesquioxane (HSQ) or SiOF. The ILD 150 may be a single layer structure or a multi-layer structure.

The contacts 164 are disposed on the S/D region 142. The contacts 164 penetrate the ILD 150. The contacts 166 are disposed on the S/D region 144. The contacts 166 penetrate the ILD 150. The contacts 164 and 166 include copper, gold, silver, nickel, titanium, platinum, or other suitable materials.

A silicide layer (not shown) may be formed between the contacts 164 and the substrate 102 or between the contacts 166 and the substrate 102. The silicide layer includes NiSi, PtSi, TiSi or any suitable metal silicide material.

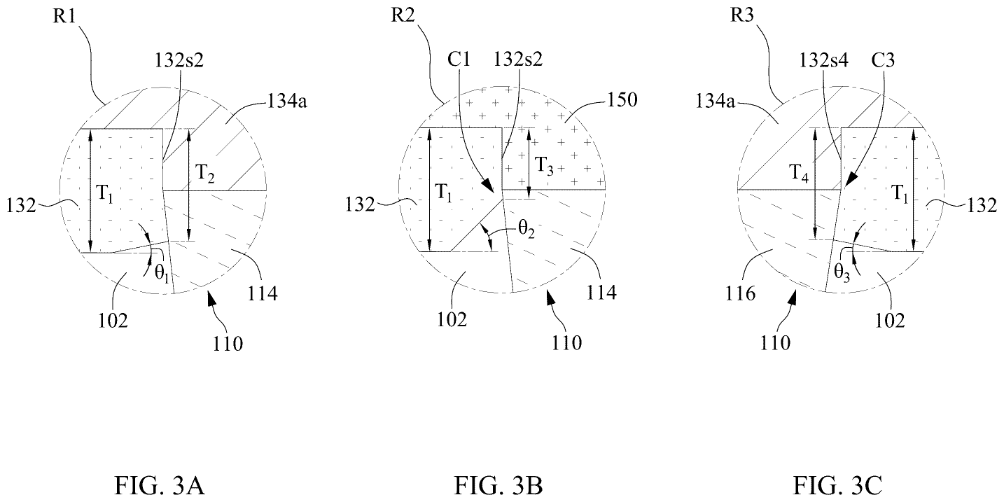

FIGS. 3A, 3B, and 3C illustrate partial enlarged views of the regions R1, R2, and R3 as shown in FIGS. 2A and 2B. The region R1 abuts the side 132s2 of the gate dielectric 132 and is far from the corner of the gate dielectric 132. The region R2 abuts the corner C1 which abuts the isolation layer 114 with a greater thickness (or depth). The region R3 abuts the corner C3 which abuts the isolation layer 116 with a smaller thickness (or depth).

In some embodiments, the gate dielectric 132 has a deformed profile due to the stress generated by the isolation structure 110 which has a greater thickness (or depth). For example, the gate dielectric 132 has a tapered profile tapered toward the side (or edge) of the gate dielectric 132 or toward the boundary between the gate dielectric 132 and the isolation structure 110. An increased depth of the isolation structure 110 results in a greater deformation of the gate dielectric 132. Further, a greater stress is imposed on the gate dielectric 132 at the corner defined by the gate dielectric 132 and the isolation structure 110, resulting in a much sharper profile. As shown in FIGS. 3A and 3B, the lower surface (not denoted) of the gate dielectric 132 and the substrate 102 define an angle θ₁ at the region R1 and an angle θ₂ at the region R2. In some embodiments, the angle θ₁ is less than the angle θ₂ because the gate dielectric 132 experiences less stress in the region R1 compared to the region R2 which is closer to the corner C1 than the region R1 is. As shown in FIG. 3C, the lower surface of the gate dielectric 132 and the substrate 102 define an angle θ₃ at the region R3. In some embodiments, the angle θ₃ is less than the angle θ₂ because the gate dielectric 132 experiences less stress in the region R3 compared to the region R2 which abuts the isolation structure 110 (e.g., the isolation layer 114) with a larger thickness_{.}

As shown in FIG. 3A, the gate dielectric 132 has a thickness T₁ far from the side (or edge) of the gate dielectric 132 and a thickness T₂ at the side (e.g., side 132s2). In some embodiments, the thickness T₁ is greater than the thickness T₂. As shown in FIG. 3B, the gate dielectric 132 has a thickness T₃ at the corner (e.g., corner C1) of the gate dielectric 132. In some embodiments, the thickness T₁ is greater than the thickness T₃. In some embodiments, the thickness T₂ is greater than the thickness T₃. As shown in FIG. 3C, the gate dielectric 132 has a thickness T₄ abutting the corner C3. In some embodiments, the thickness T₄ is greater than the thickness T₃.

When a high voltage is applied to a semiconductor device, a gate dielectric may experience burnout at the corner due to its relatively small thickness at that point. This degradation may adversely affect the performance of the semiconductor device.

Referring back to FIG. 1, in some embodiments, the gate electrode 134a has a modified profile. For example, the gate electrode 134a defines a recess 136a1 (or opening or cavity) at the corner C1. In some embodiments, the gate electrode 134a defines a recess 136a2 at the corner C2. The recesses 136a1 and 136a2 of the gate electrode 134a are configured to mitigate the intensity of the electric field at the corners C1 and C2. Consequently, when a high voltage is applied to the semiconductor device 10a, the gate dielectric 132 adjacent to corners C1 and C2, where the gate dielectric 132 has a relatively small thickness, is protected from burnout.

In some embodiments, the recess 136a1 (or 136a2) has a closed profile, which indicates that the edges (or sides) are joined together in a top view. In some embodiments, the recesses 136a1 and 136a2 have a rectangular profile or a square-shaped profile. For example, the gate electrode 134a has sides 136s1, 136s2, 136s3, and 136s4 (or lateral surfaces or edges) defining the recess 136a1. The sides 136s1 and 136s3 extend along the X direction. The sides 136s2 and 136s4 extend along the Y direction. The side 136s2 is closer to the S/D region 144 than the side 136s4 is. In some embodiments, the recesses 136a1 and 136a2 expose the gate dielectric 132 (or substrate 102). In some embodiments, the recesses 136a1 and 136a2 expose the isolation structure 110. In some embodiments, the recesses 136a1 and 136a2 are filled by the ILD 150. In some embodiments, the geometry center (e.g., point P1) of the recess 136a1 and the corner C1 have a non-zero distance therebetween. In some embodiments, the gate electrode 134a has a portion extending between the recesses 136a1 and 136a2 along the Y direction. In some embodiments, the gate electrode 134a has a portion extending between the corners C1 and C2 along the Y direction.

As shown in FIG. 2B, the corner C1 is exposed by the gate electrode 134a. In some embodiments, the corner C1 is covered by the ILD 150. In some embodiments, the ILD 150 has a portion 150p1 (or part) surrounded or enclosed by the gate electrode 134a. The portion 150p1 has an elevation (or level), with respect to the upper surface of the substrate 102, substantially the same as that of the gate electrode 134a. In some embodiments, the portion 150p1 of the ILD 150 covers a portion of the gate dielectric 132 and a portion of the isolation layer 114. In some embodiments, the portion 150p1 of the ILD 150 is in contact with a portion of the gate dielectric 132 and a portion of the isolation layer 114. In this cross-sectional view, the gate electrode 134a includes a portion 134p1 and a portion 134p2 spaced apart from the portion 134p1 by the ILD 150. In some embodiments, a tapered portion 132p1 (or deformed portion) of the gate dielectric 132 is exposed by the gate electrode 134a. In some embodiments, the tapered portion 132p1 of the gate dielectric 132 is covered by the portion 150p1 of the ILD 150.

Referring back to FIG. 1, the recess 136a1 has a length (or width) X₁ along the X direction. The side 136s4 of the recess 136 and the side 132s2 of the gate dielectric 132 define a length (or distance) X₂ along the X direction in a top view. In some embodiments, the ratio of the length X₂ to the length X₁ ranges between 0.25 and 0.7, such as 0.25, 0.3, 0.35, 0.4, 0.45, 0.5, 0.6, or 0.7. When the ratio of the length X₂ to the length X₁ is greater than or equal to 0.25, the tapered portion 132p1 of the gate dielectric 132 is sufficiently distanced from the intense electric field during operation. When the ratio of length X₂ to the length X₁ is less than or equal to 0.7, the channel region of the semiconductor device 10a is adequately covered by the gate electrode 134a, facilitating optimal operation of the semiconductor device 10a.

The recess 136a1 has a length (or width) Y₁ along the Y direction. The side 136s3 of the recess 136 and the side 132s1 of the gate dielectric 132 define a length (or distance) Y₂ along the Y direction in a top view. In some embodiments, the ratio of the length Y₂ to the length Y₁ ranges between 0.25 and 0.7, such as 0.25, 0.3, 0.35, 0.4, 0.45, 0.5, 0.6, or 0.7. When the ratio of the length Y₂ to the length Y₁ is greater than or equal to 0.25, the tapered portion 132p1 of the gate dielectric 132 is sufficiently distanced from the intense electric field during operation. When the ratio of length Y₂ to the length Y₁ is less than or equal to 0.7, the channel region of the semiconductor device 10a is adequately covered by the gate electrode 134a, facilitating optimal operation of the semiconductor device 10a.

The gate electrode 134a exceeds the edge of the gate dielectric 132. For example, the gate electrode 134a exceeds the sides 132s1, 132s2, 132s3, and 132s4 of the gate dielectric 132. For example, the sides 134s1 and 134s2 of the gate electrode 134a are located over the isolation structure 110. The side 134s1 of the gate electrode 134 and the side 132s1 have a distance D₁ in a top view. In some embodiments, the ratio of the distance D₁ to the length Y₁ is greater than 0.2 for improved electrical properties.

In some embodiments, the percentage of substrate 102 that overlaps with gate electrode 134a along the Z direction at side 132s2 of gate dielectric 132 is less than the percentage of substrate 102 that overlaps with gate electrode 134a along the Z direction at side 132s4 of gate dielectric 132. For example, the substrate 102 has a portion 102p1 (or part) abutting the side 132s2 of the gate dielectric 132 and a portion 102p2 (or part) abutting the side 132s4 of the gate dielectric 132. The portion 102p1 may indicate a region (or area) of the substrate 102, which expands from the side 132s2 along the X direction, extending along the Y direction. The portion 102p2 may indicate a region (or area), which expands from the side 132s4 along the X direction, extending along the Y direction. Since a portion of the portion 102p1 is exposed by the recesses 136a1 and 136a2, the percentage of the portion 102p1 covered by the gate electrode 134a is less than that of the portion 102p2 covered by the gate electrode 134a.

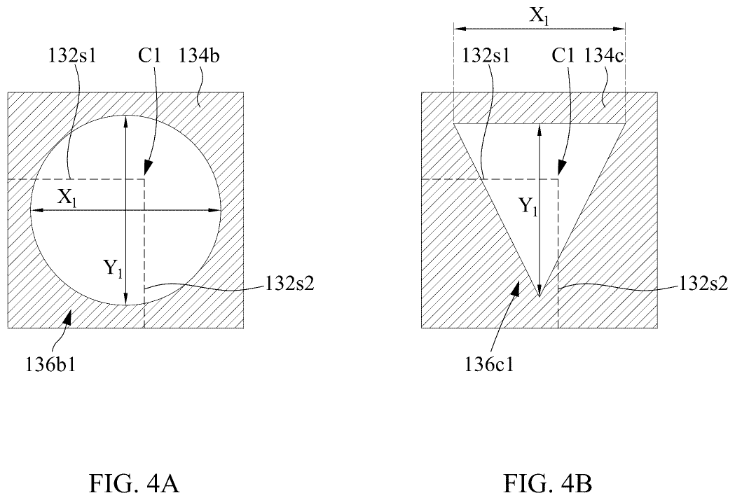

FIG. 4A and FIG. 4B illustrate top views of gate electrodes, in accordance with some embodiments of the present disclosure.

In some embodiments, the gate electrode 134a as shown in FIG. 1 can have other profiles. As shown in FIG. 4A, the gate electrode 134a may be replaced by a gate electrode 134b. The gate electrode 134b may include a recess 136b1 abutting the corner C1. In some embodiments, the recess 136b1 has a circular profile, an elliptical profile, or an oval profile. In this embodiment, the length X₁ and/or length Y₁ may indicate the diameter of the recess 136b1. As shown in FIG. 4B, the gate electrode 134a may be replaced by a gate electrode 134c. The gate electrode 134c may include a recess 136c1 abutting the corner C1. In some embodiments, the recess 136c1 has a triangular profile, such as an equilateral triangle-shaped profile, isosceles triangle-shaped profile, or scalene triangle-shaped profile. In this embodiment, the length X₁ may indicate the length of the edge of the recess 136c1, and the length Y₁ may indicate a distance between the vertex and the edge of the recess 136c1.

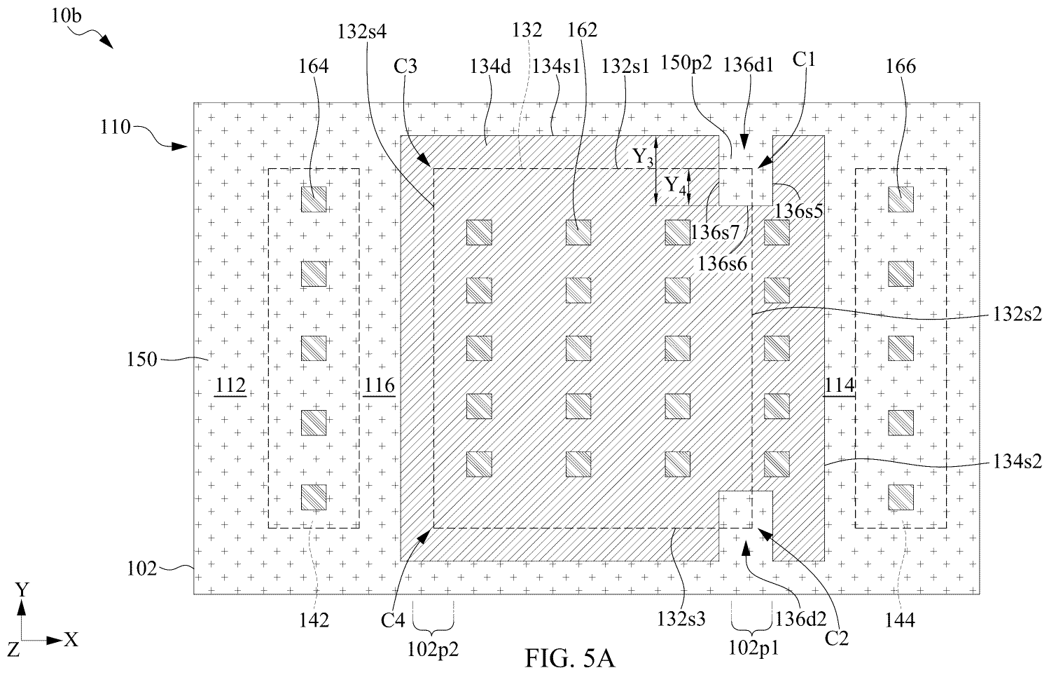

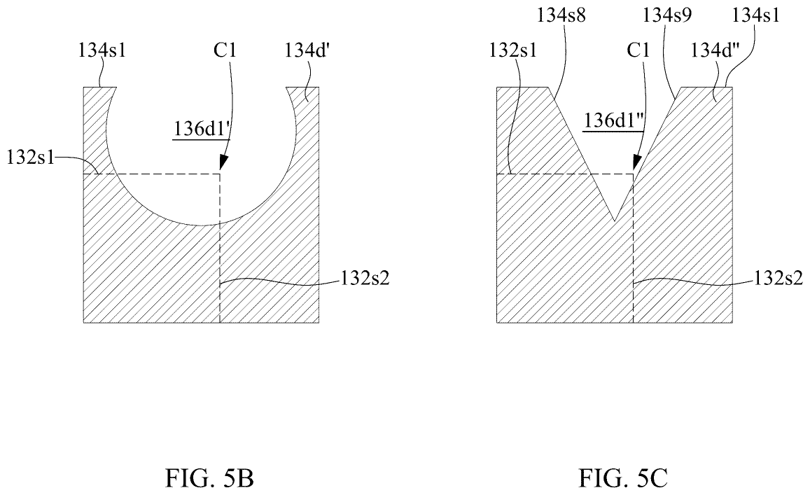

FIG. 5A is a top view of a semiconductor device 10b, in accordance with some embodiments of the present disclosure. In some embodiments, the semiconductor device 10b has a structure similar to that of the semiconductor device 10a, and one of the differences between them is that the semiconductor device 10b includes a gate electrode 134d including recesses with opened profiles.

In some embodiments, the gate electrode 134d defines a recess 136d1 abutting the corner C1. In some embodiments, the gate electrode 134d defines a recess 136d2 abutting the corner C2. Each of the recess 136d1 and recess 136d2 has an opened profile. In some embodiments, the recess 136d1 is recessed from the side 134s1 of the gate electrode 134. The gate electrode 134d has a side 136s5, a side 136s6, and a side 136s7 defining the recess 136d1. The sides 136s5 and 136s7 extend along the Y direction. The side 136s6 extends along the X direction and between the side 136s5 and side 136s7. In some embodiments, the ILD 150 has a protruding portion 150p2 extending into the gate electrode 134d and filling the recess 136d1.

The side 136s7 has a length (or width) Y₃ along the Y direction. The side 136s6 of the gate electrode 134d and the side 132s1 of the gate dielectric 132 define a length (or distance) Y₄ along the Y direction in a top view. In some embodiments, the ratio of length Y₄ to length Y₃ ranges between 0.25 and 0.7, such as 0.25, 0.3, 0.35, 0.4, 0.45, 0.5, 0.6, or 0.7. When the ratio of length Y₄ to length Y₃ is greater than or equal to 0.25, the tapered portion of the gate dielectric 132 is sufficiently distanced from the intense electric field during operation. When the ratio of length Y₄ to length Y₃ is less than or equal to 0.7, the channel region of the semiconductor device 10b is adequately covered by the gate electrode 134d, facilitating optimal operation of the semiconductor device 10b.

FIGS. 5B and 5C illustrate top views of gate electrodes, in accordance with some embodiments of the present disclosure.

In some embodiments, the gate electrode 134d as shown in FIG. 5A can have other profiles. As shown in FIG. 5B, the gate electrode 134d may be replaced by a gate electrode 134d′. The gate electrode 134d′ may include a recess 136d1′ abutting the corner C1. In some embodiments, the recess 136d1 has a partial circular profile, a partial elliptical profile, or a partial oval profile. As shown in FIG. 5B, the gate electrode 134d may be replaced by a gate electrode 134d″. The gate electrode 134d″ may include a recess 136d1″ abutting the corner C2. In some embodiments, the gate electrode 134d″ includes a side 136s8 and a side 136s9 defining the recess 136d1″. The side 136s8 is slanted with respect to the side 134s1. The side 136s9 is slanted with respect to the side 134s1.

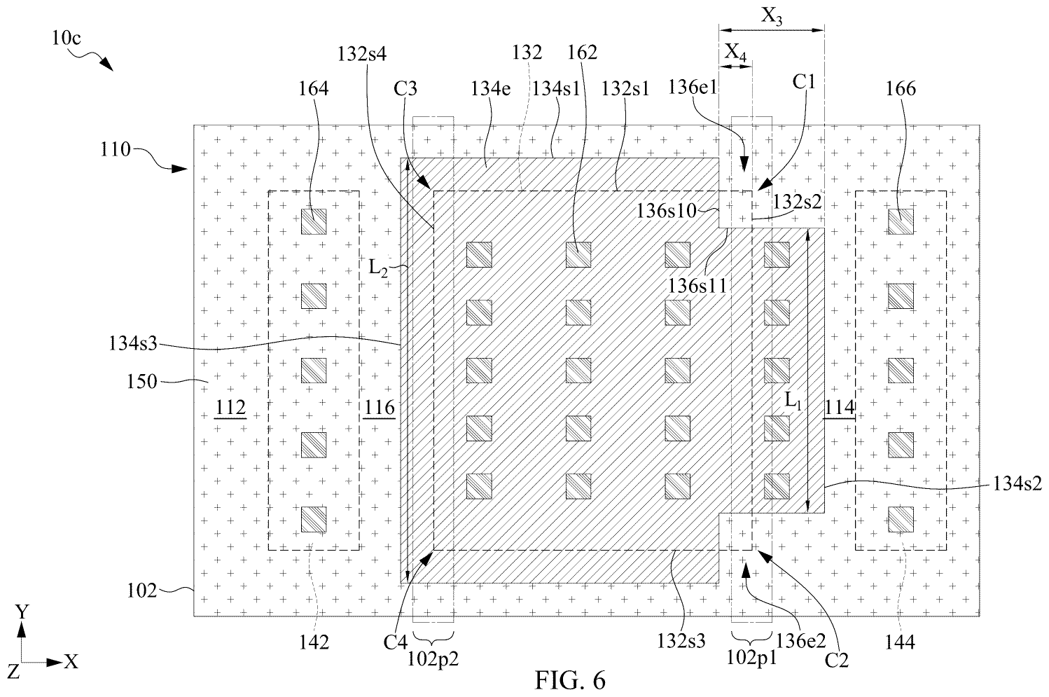

FIG. 6 is a top view of a semiconductor device 10c, in accordance with some embodiments of the present disclosure. In some embodiments, the semiconductor device 10c has a structure similar to that of the semiconductor device 10a, and one of the differences between them is that the semiconductor device 10c includes a gate electrode 134e including recesses with opened profiles.

In some embodiments, the gate electrode 134e defines a recess 136e1 abutting the corner C1. In some embodiments, the gate electrode 134e defines a recess 136e2 abutting the corner C2. Each of the recess 136e1 and recess 136e2 has an opened profile. In some embodiments, the recess 136e1 is an indentation recessed from the sides 134s1 and side 134s2 of the gate electrode 134e. The gate electrode 134e has a side 136s10 and a side 136s11 defining the recess 136e1; the side 136s10 extends along the Y direction, and the side 136s11 extends along the X direction. The gate electrode 134 has a side 134s3 abutting the S/D region 142. In some embodiments, the length L₁ of the side 134s2 is less than the length L₂ of the side 134s2 along the Y direction.

The side 136s11 has a length (or width) X₃ along the X direction. The side 136s10 of the gate electrode 134e and the side 132s2 of the gate dielectric 132 define a length (or distance) X₄ along the X direction in a top view. In some embodiments, the ratio of length X₄ to length X₃ ranges between 0.25 and 0.7, such as 0.25, 0.3, 0.35, 0.4, 0.45, 0.5, 0.6, or 0.7. When the ratio of length X₄ to length X₃ is greater than or equal to 0.25, the tapered portion of the gate dielectric 132 is sufficiently distanced from the intense electric field during operation. When the ratio of length X₄ to length X₃ is less than or equal to 0.7, the channel region of the semiconductor device 10c is adequately covered by the gate electrode 134e, facilitating optimal operation of the semiconductor device 10c.

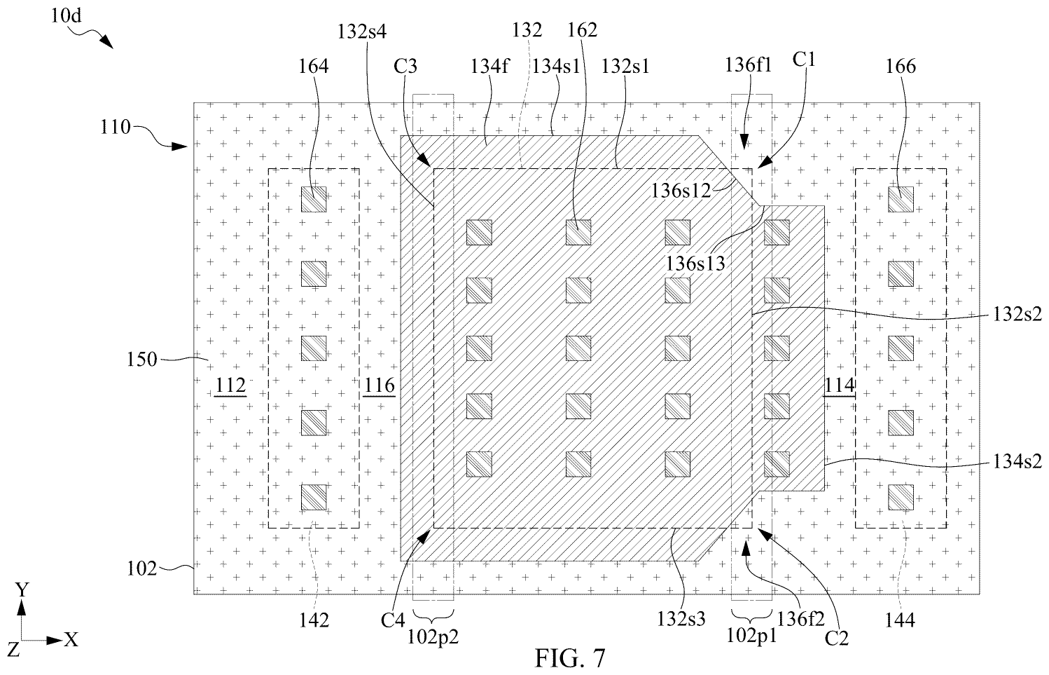

FIG. 7 is a top view of a semiconductor device 10d, in accordance with some embodiments of the present disclosure. In some embodiments, the semiconductor device 10d has a structure similar to that of the semiconductor device 10a, and one of the differences between them is that the semiconductor device 10d includes a gate electrode 134f including recesses with opened profiles.

In some embodiments, the gate electrode 134f defines a recess 136f1 abutting the corner C1. In some embodiments, the gate electrode 134f defines a recess 136f2 abutting the corner C2. Each of the recess 136f1 and recess 136f2 has an opened profile. The gate electrode 134f1 has a side 136s12 and a side 136s13 defining the recess 136f1. The side 136s12 extends between the side 134s1 and the side 136s13. The side 136s13 extends between the side 134s2 and the side 136s12. In some embodiments, the side 136s12 is slanted with respect to the side 134s1. In some embodiments, the side 136s12 is slanted with respect to the side 136s13. In some embodiments, the side 136s12 and side 136s13 define an obtuse angle.

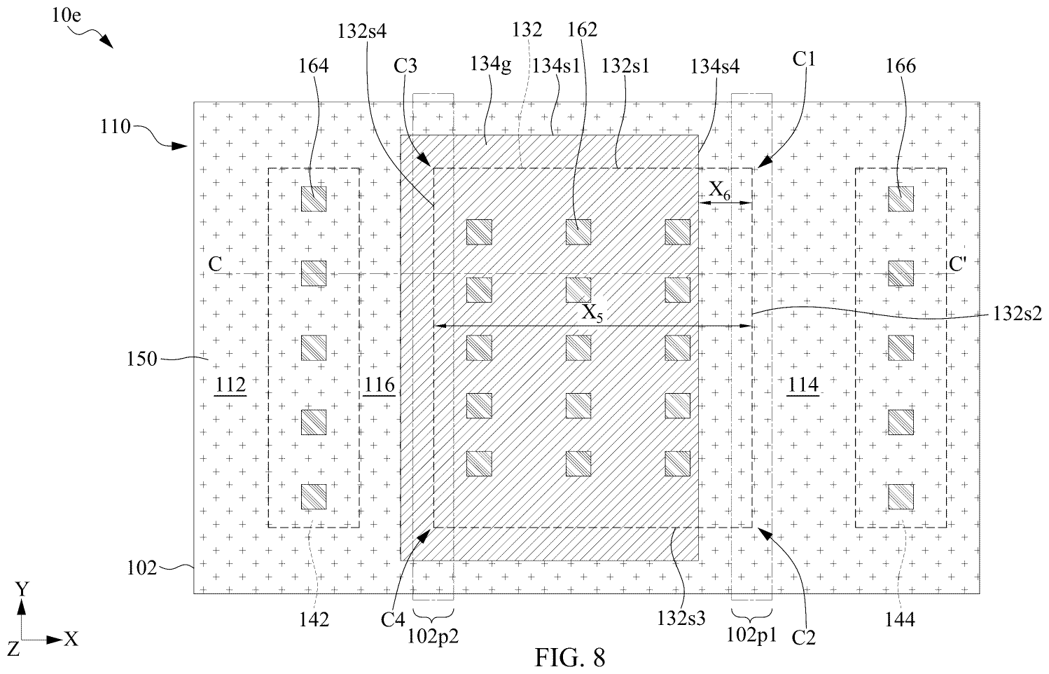

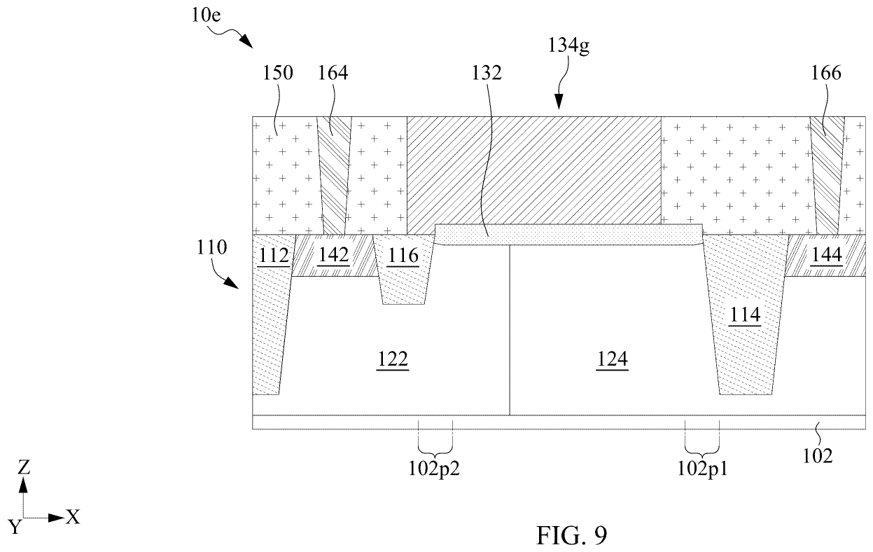

FIG. 8 and FIG. 9 illustrate a semiconductor device 10e in accordance with some embodiments of the present disclosure. FIG. 8 is a top view of the semiconductor device 10e, and FIG. 9 is a cross-sectional view along line C-C′ of FIG. 8. In some embodiments, the semiconductor device 10e has a structure similar to that of the semiconductor device 10a, and one of the differences between them is that the semiconductor device 10e includes a gate electrode 134g recessed from the side 132s2 of the gate dielectric 132 in a top view.

In some embodiments, the side 132s2 of the gate dielectric 132 is completely free from being covered by the gate electrode 134g. In some embodiments, the gate electrode 134g has a side 134s4 facing the S/D region 144. In some embodiments, the side 134s4 is free from overlapping the isolation layer 114 along the Z direction. The gate dielectric 132 has a length X₅ along the X direction. The side 134s4 of the gate electrode 134g and the side 132s2 of the gate dielectric 132 have a length (or distance) X₆ along the X direction. In some embodiments, the ratio of length X₆ to length X₅ is greater than 5%, such as 5%, 7%, 10%, or 15%. When the ratio of length X₆ to length X₅ is greater than or equal to 5%, the tapered portion of the gate dielectric 132 is sufficiently distanced from the intense electric field during operation.

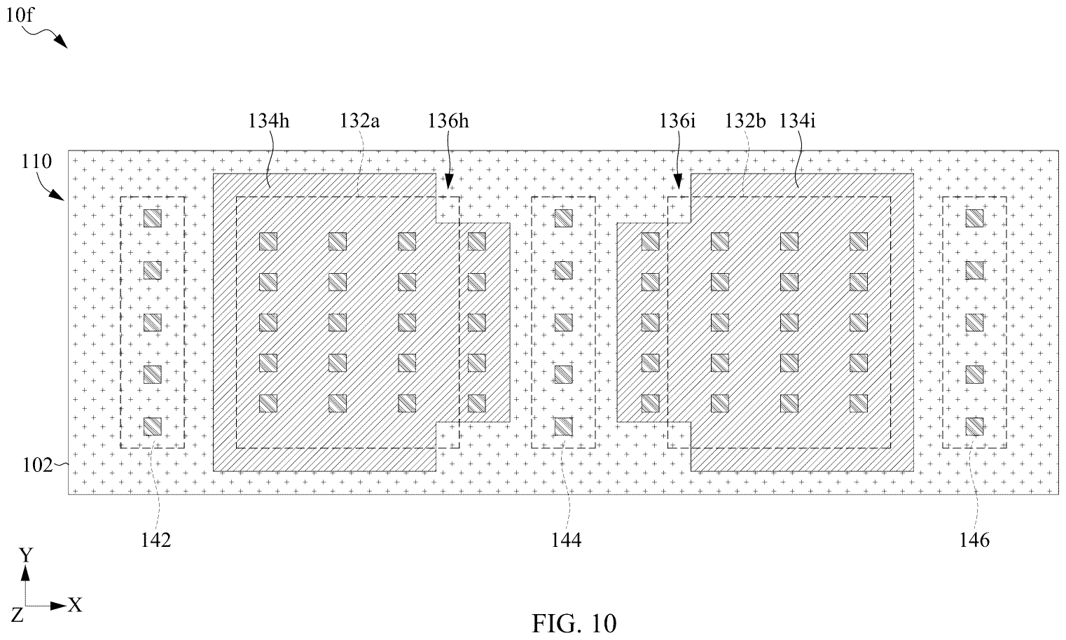

FIG. 10 is a top view of a semiconductor device 10f, in accordance with some embodiments of the present disclosure. In some embodiments, the semiconductor device 10f has a structure similar to that of the semiconductor device 10a, and one of the differences between them is that the semiconductor device 10f includes a common drain structure.

In some embodiments, the semiconductor device 10f further includes an S/D region 146. The S/D region 144 is disposed between the S/D regions 142 and 146. In some embodiments, the S/D region 144 functions as a common drain, and each of the S/D regions 142 and 146 functions as a source. The semiconductor device 10f includes a gate electrode 134h and a gate electrode 134i. The gate electrode 134h defines a recess 136h that abuts the S/D region 144 and is at the corner of a gate dielectric 132a. The gate electrode 134i defines a recess 136i that abuts the S/D region 144 and is at the corner of a gate dielectric 132b. In some embodiments, the recess 136h faces the recess 136i. Although FIG. 10 illustrates that each of the recesses 136g and 136i has a profile the same as or similar to that of the recess 136e1, the recesses 136g and 136i can have other profiles. For example, the recesses 136g and 136i can have a closed-profile as shown in FIG. 1.

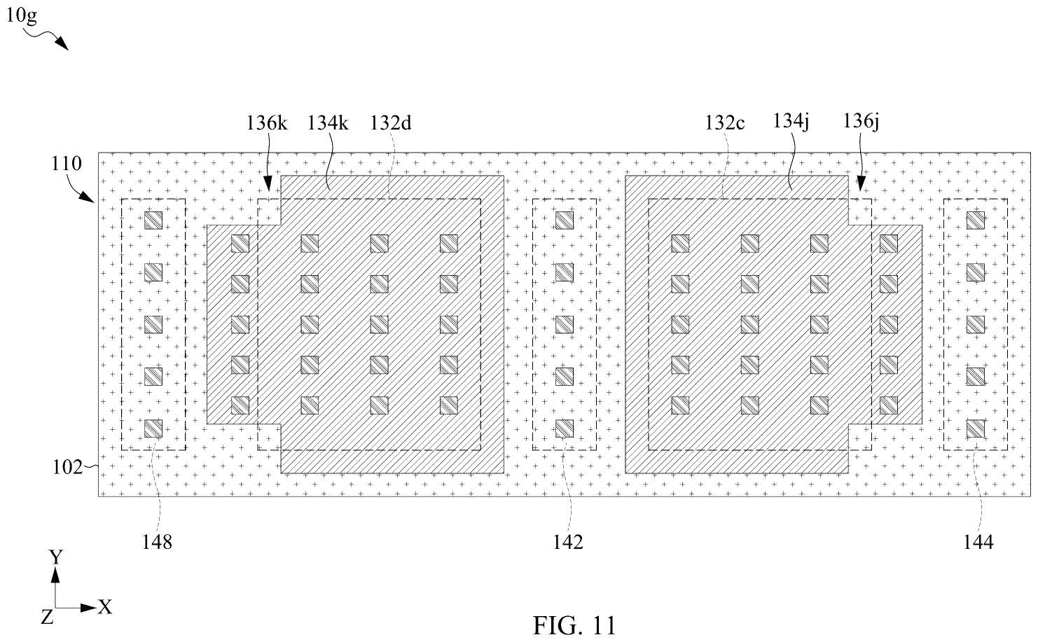

FIG. 11 is a top view of a semiconductor device 10g, in accordance with some embodiments of the present disclosure. In some embodiments, the semiconductor device 10g has a structure similar to that of the semiconductor device 10a, and one of the differences between them is that the semiconductor device 10g includes a common source structure.

In some embodiments, the semiconductor device 10g further includes an S/D region 148. The S/D region 142 is disposed between the S/D regions 144 and 148. In some embodiments, the S/D region 142 functions as a common source, and each of the S/D regions 144 and 148 functions as a drain. The semiconductor device 10g includes a gate electrode 134j and a gate electrode 134k. The gate electrode 134j defines a recess 136j that abuts the S/D region 144 and is at the corner of a gate dielectric 132c. The gate electrode 134k defines a recess 136k that abuts the S/D region 148 and is at the corner of a gate dielectric 132d. In some embodiments, the recess 136j faces away from the recess 136k. Although FIG. 11 illustrates that each of the recesses 136j and 136k has a profile the same as or similar to that of the recess 136e1, the recesses 136j and 136k can have other profiles. For example, the recesses 136j and 136k can have a closed-profile as shown in FIG. 1.

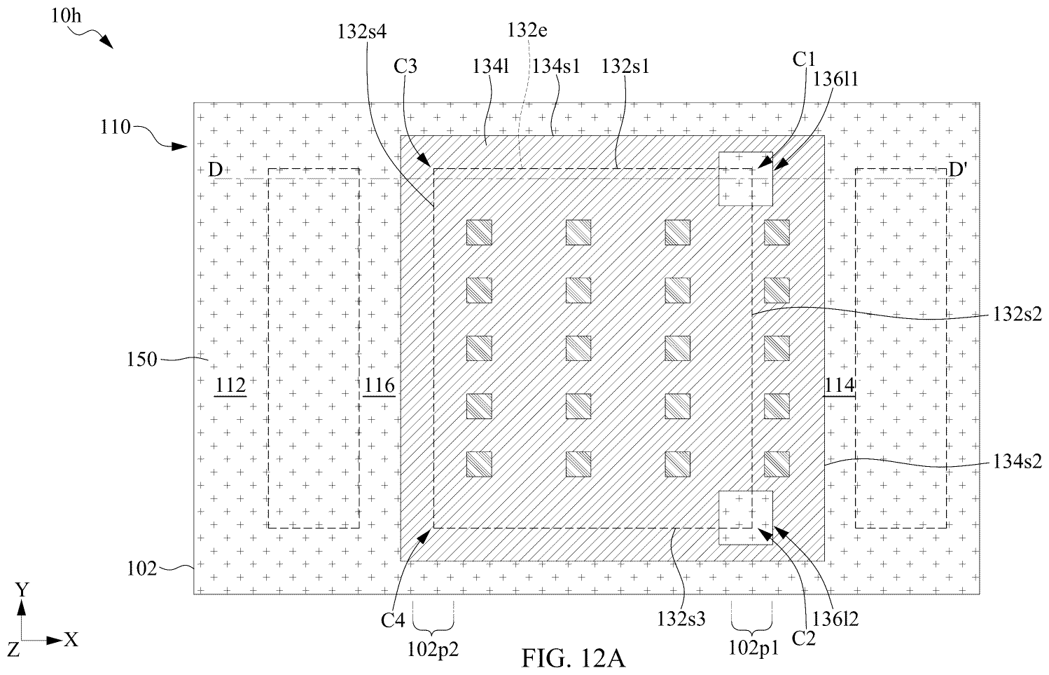

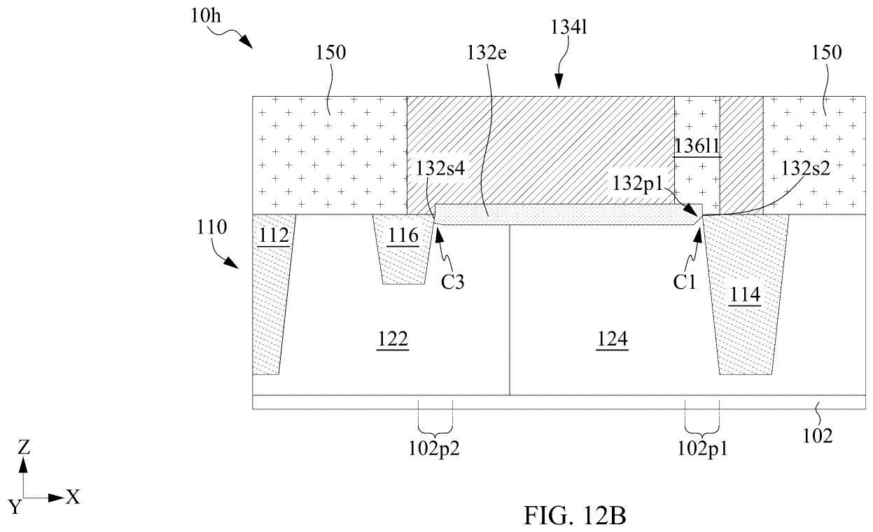

FIG. 12A and FIG. 12B illustrate a semiconductor device 10h, in accordance with some embodiments of the present disclosure. FIG. 12A is a top view, and FIG. 12B is a cross-sectional view along line D-D′ of FIG. 12A. In some embodiments, the semiconductor device 10h has a structure similar to that of the semiconductor device 10a, and one of the differences between them is that the semiconductor device 10h includes a resistor structure.

In some embodiments, the semiconductor device 10h functions as a resistor region of a device (e.g., a high-voltage semiconductor device). The semiconductor device 10h includes a dielectric layer 132e and an electrode 134l over the dielectric layer 132e. The dielectric layer 132e has a structure similar to or the same as that of the gate dielectric 132. The electrode 134l may define a recess 136l1 and a recess 136l2. In some embodiments, the recess 136l1 abuts the corner C1. In some embodiments, the recess 136l2 abuts the corner C2. The recesses 136l1 and 136l2 are configured to mitigate the intensity of the electric field at the corners C1 and C2. Consequently, when a high voltage is applied to the semiconductor device 10h, the dielectric layer 132e is protected from burnout.

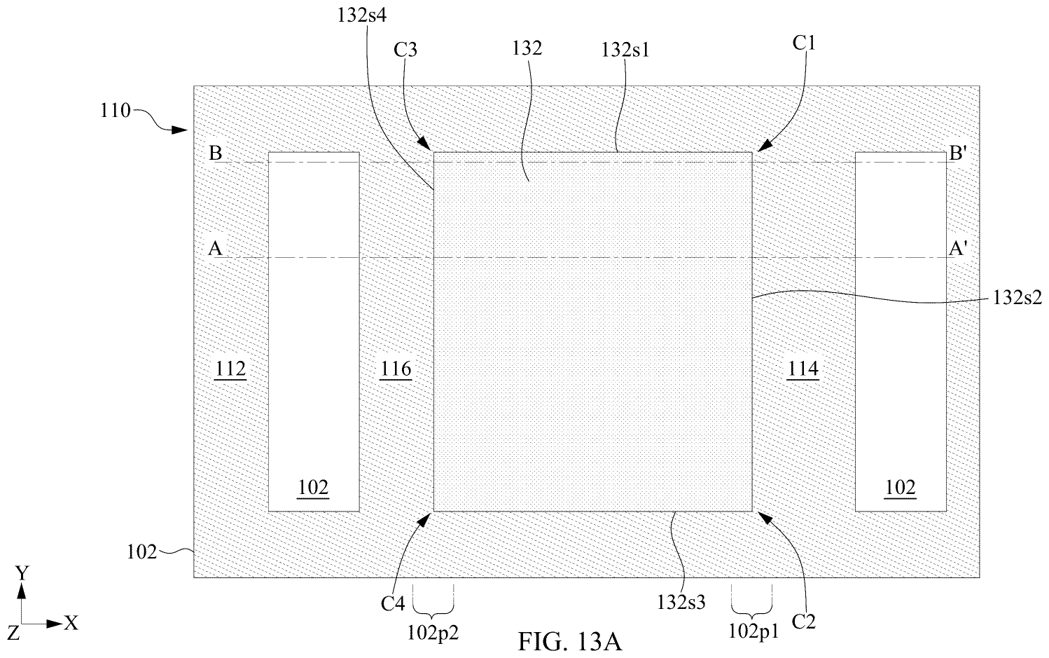

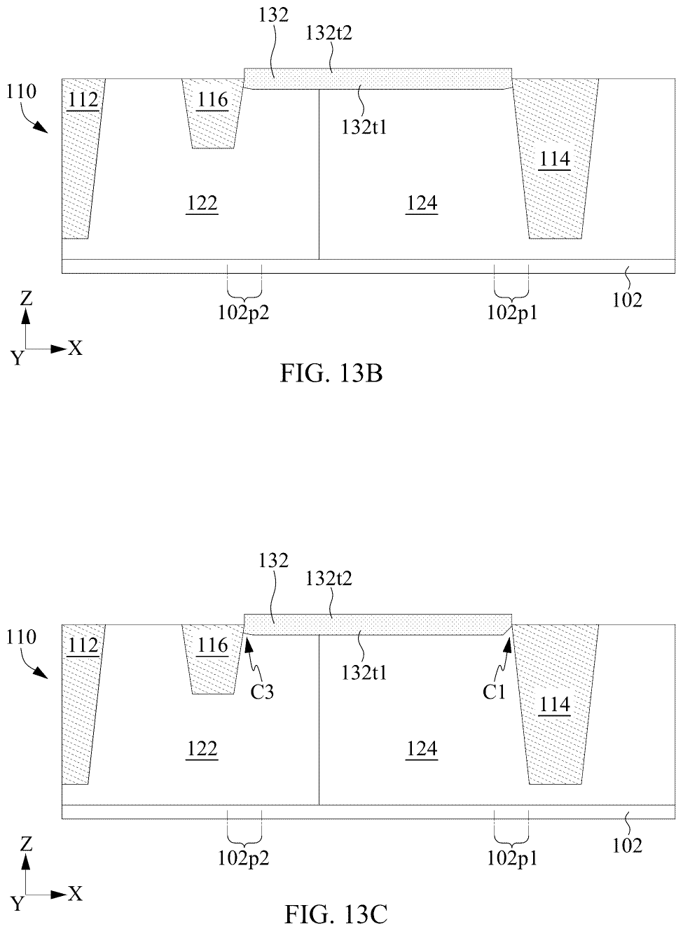

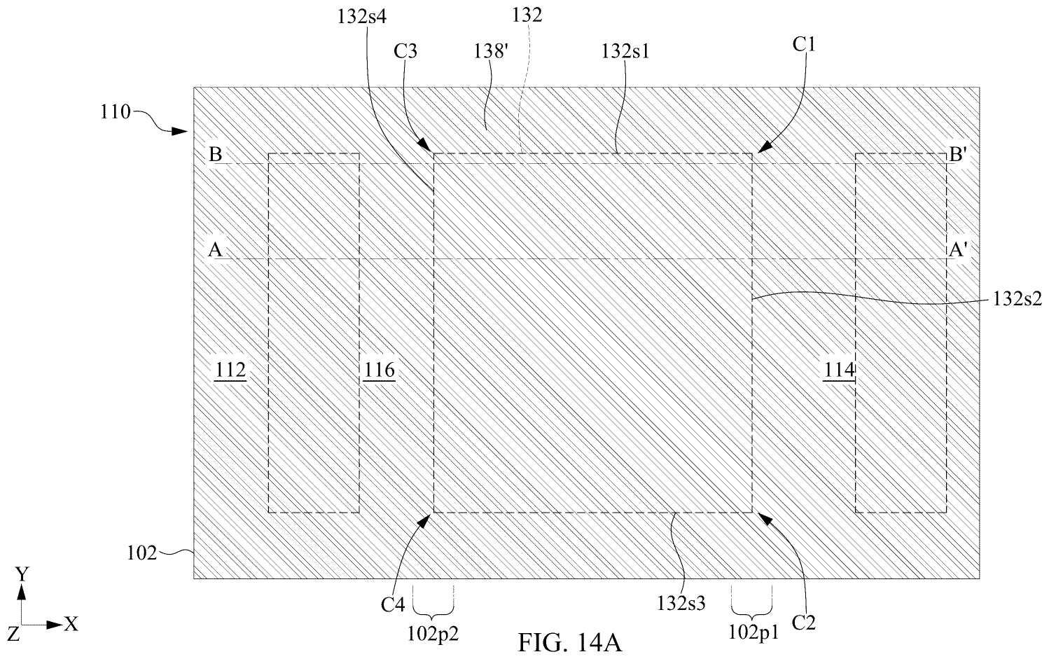

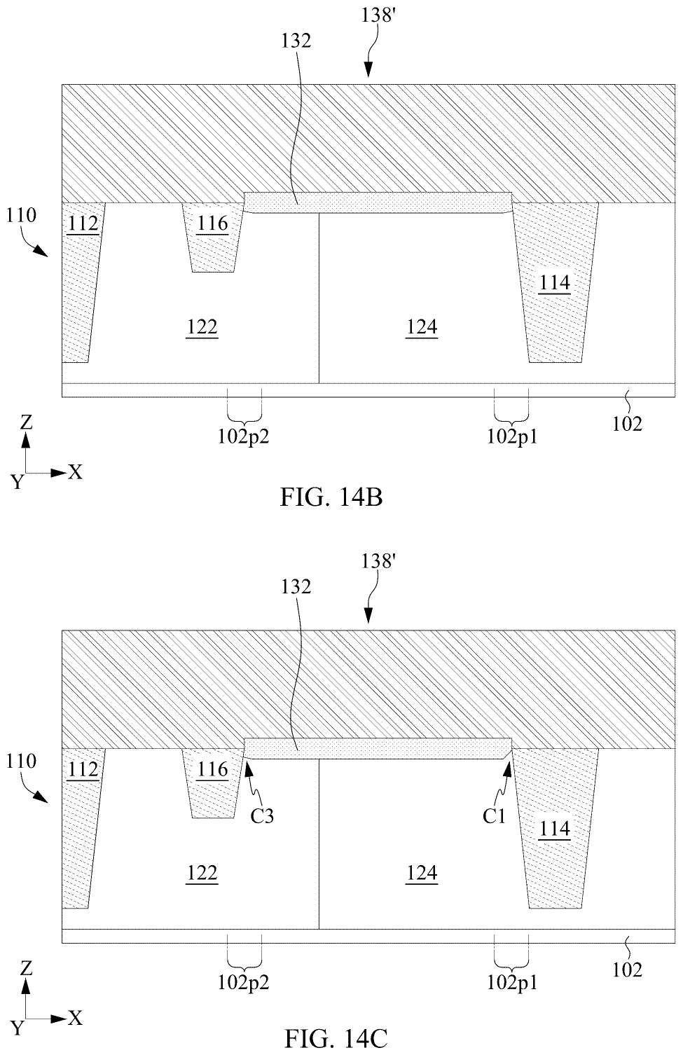

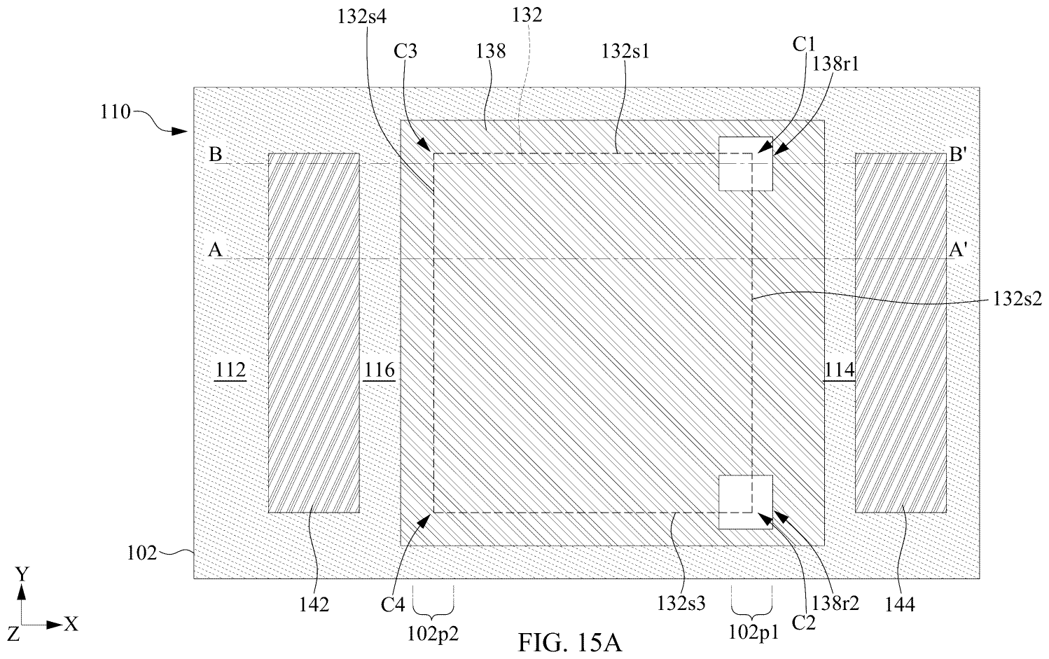

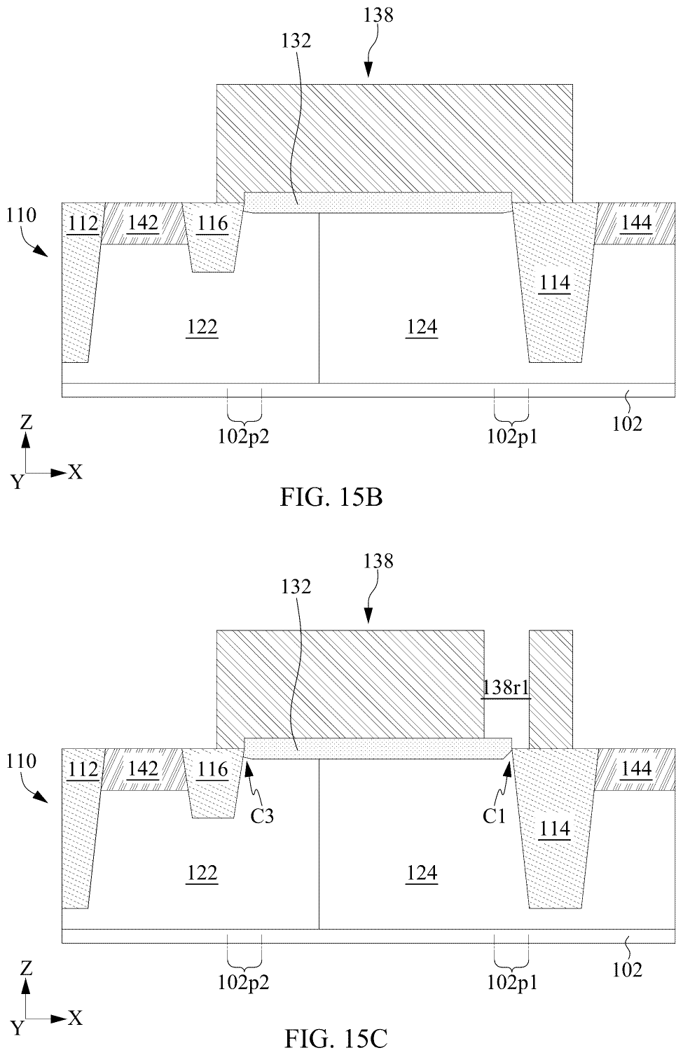

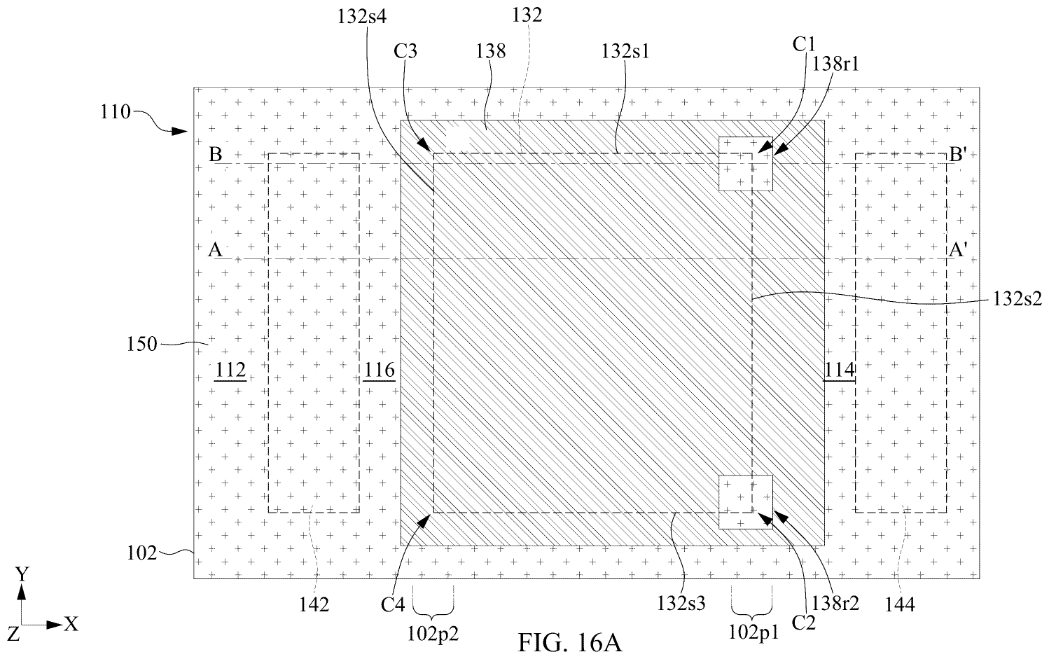

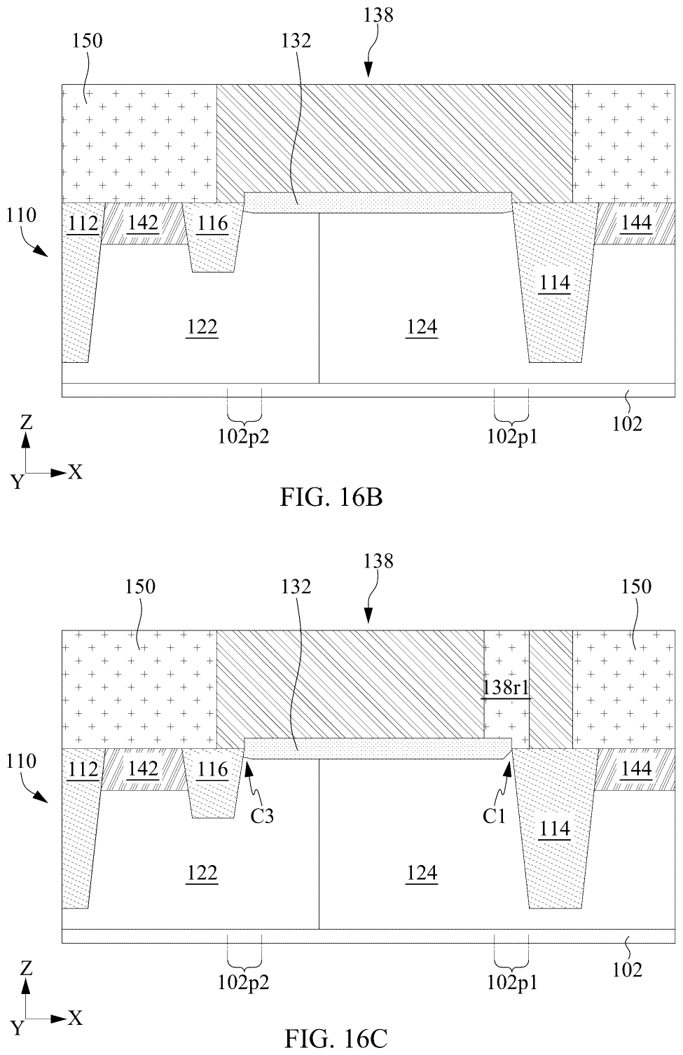

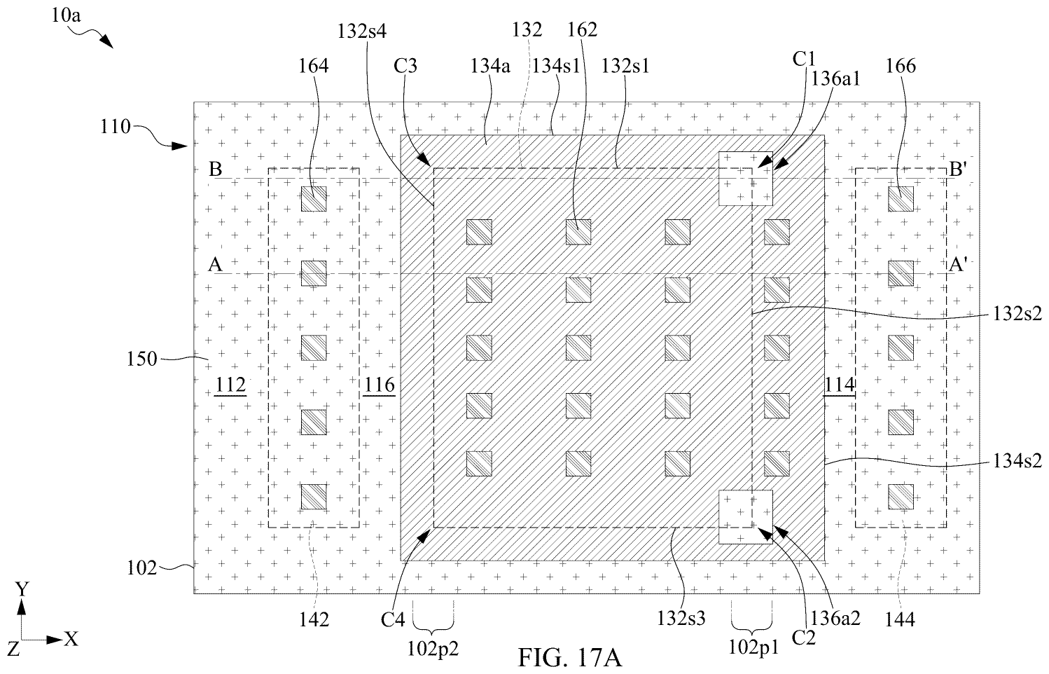

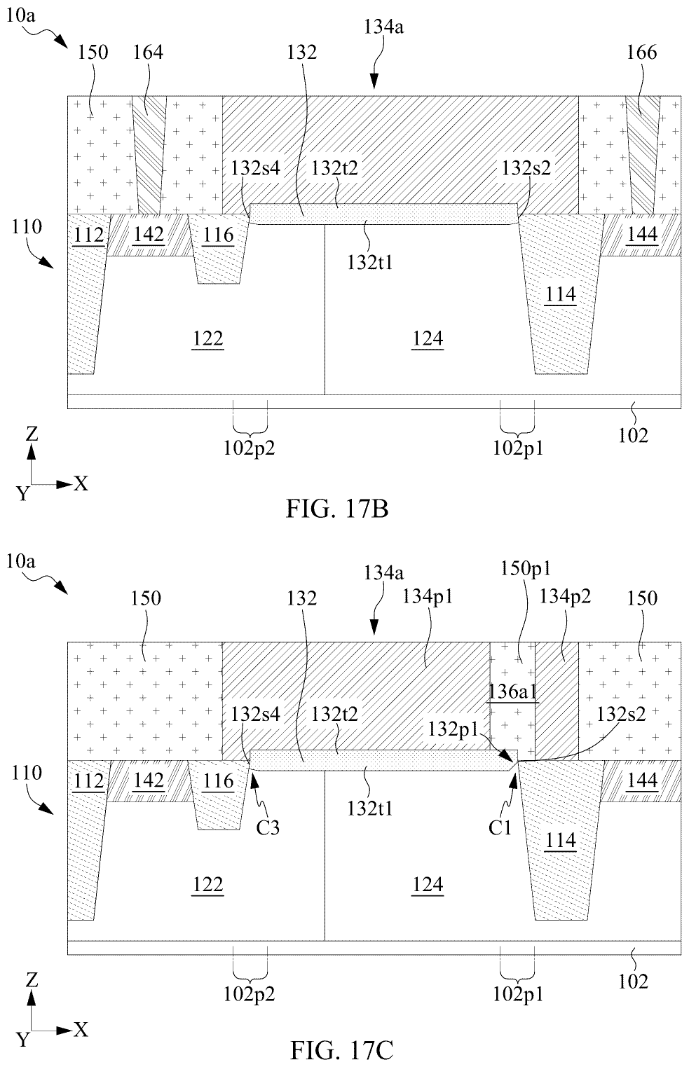

FIGS. 13A to 17A, FIGS. 13B to 17B, and FIGS. 13C to 17C illustrate various stages of manufacturing a semiconductor device, in accordance with some embodiments of the present disclosure. FIGS. 13A to 17A are top views, FIGS. 13B to 17B are cross-sectional views along line A-A′ of FIG. 13A to FIG. 17A, and FIGS. 13C to 17C are cross-sectional views along line B-B′ of FIG. 13A to FIG. 17A, respectively.

Referring to FIGS. 13A, 13B, and 13C, the substrate 102 is provided. The isolation structure 110 is formed within the substrate 102. In some embodiments, the isolation structure 110 includes a liner oxide (not shown), which may be a thermal oxide formed through a thermal oxidation of a surface layer of the substrate 102. The liner oxide may also be a deposited silicon oxide layer formed using, for example, atomic layer deposition (ALD), high-density plasma chemical vapor deposition (HDPCVD), chemical vapor deposition (CVD), or other suitable techniques. The isolation structure 110 may also include a dielectric material over the liner oxide, wherein the dielectric material may be formed using flowable chemical vapor deposition (FCVD), spin-on, or the like. In some embodiments, the substrate 102 is etched to form trenches, and a dielectric material is deposited to fill the trenches, which thereby forms the isolation structure 110. The etching technique may be performed using a dry etching process, wherein HF₃ and NH₃ are used as the etching gases. In accordance with alternative embodiments of the present disclosure, the recessing of isolation structure 110 is performed using a wet etch process. The etching chemical may include HF solution, for example.

The gate dielectric 132 is formed on the substrate 102. In some embodiments, the gate dielectric 132 is formed by two or more steps or processes. For example, a thermal technique (e.g., thermal oxidation) is performed to form the portion 132t1 of the gate dielectric 132, and then a deposition technique (e.g., CVD) is performed to form the portion 132t2 of the gate dielectric 132. The gate dielectric 132 and the isolation structure 110 define the corners C1 and C2 abutting the isolation layer 114 and define the corners C3 and C4 abutting the isolation layer 116.

Referring to FIGS. 14A, 14B, and 14C, a dummy gate material 138′ is formed to cover the substrate 102, the isolation structure 110, and the gate dielectric 132. The dummy gate material 138′ is configured to define a dummy gate electrode in subsequent stages. In some embodiments, the dummy gate material 138′ includes polysilicon or other suitable materials. In some embodiments, the dummy gate material 138′ is formed by CVD, PVD, or other suitable techniques.

Referring to FIGS. 15A, 15B, and 15C, the dummy gate material 138′ is patterned to define a recess 138r1 (or opening or cavity) over the corner C1 and a recess 138r2 (or opening or cavity) over the corner C2. The dummy gate material 138′ is patterned by a lithography technique and an etching technique. The dummy gate electrode 138 (or dummy gate) is formed after the dummy gate material 138′ is patterned. In some embodiments, the corners C1 and C2 are exposed by the dummy gate electrode 138. The corners C3 and C4 are covered by the dummy gate electrode 138. Further, an implantation technique is performed to form the S/D regions 142 and 144 on the exposed substrate 102.

Referring to FIGS. 16A, 16B, and 16C, the ILD 150 is formed to encapsulate the dummy gate electrode 138. In some embodiments, the ILD 150 fills the recesses 138r1 and 138r2 of the dummy gate electrode 138, thereby covering the corners C1 and C2. In some embodiments, the ILD 150 is formed by CVD, PVD, or other suitable techniques. A polishing technique, such as chemical mechanical polishing (CMP), may be performed to planarize the upper surfaces of the dummy gate electrode 138 and the ILD 150.

Referring to FIGS. 17A, 17B, and 17C, the dummy gate electrode 138 is replaced by the gate electrode 134a, and the contacts 162, 164, and 166 are formed, which thereby produce a semiconductor device (e.g., the semiconductor device 10a). In some embodiments, the dummy gate electrode 138 is removed by one or more etching techniques. One or more conductive materials are formed to inherit the profile of the dummy gate electrode 138, thereby forming the gate electrode 134a. The recesses 138r1 and 138r2, filled by the ILD 150, define the recesses 136a1 and 136a2 of the gate electrode 134a. A polishing technique, such as CMP, may be performed to planarize the upper surfaces of the gate electrode 134a and the ILD 150. The ILD 150 is patterned to define multiple openings, and one or more conductive materials are formed to fill the openings, thereby producing the contacts 162, 164, and 166.

It should be noted that the profile of the recesses 138r1 and 138r2 of the dummy gate electrode 138 as shown in FIGS. 15A-15C can be modified. For example, the recesses 138r1 and 138r2 can have opened profiles. As a result, the semiconductor devices 10b to 10e can be produced.

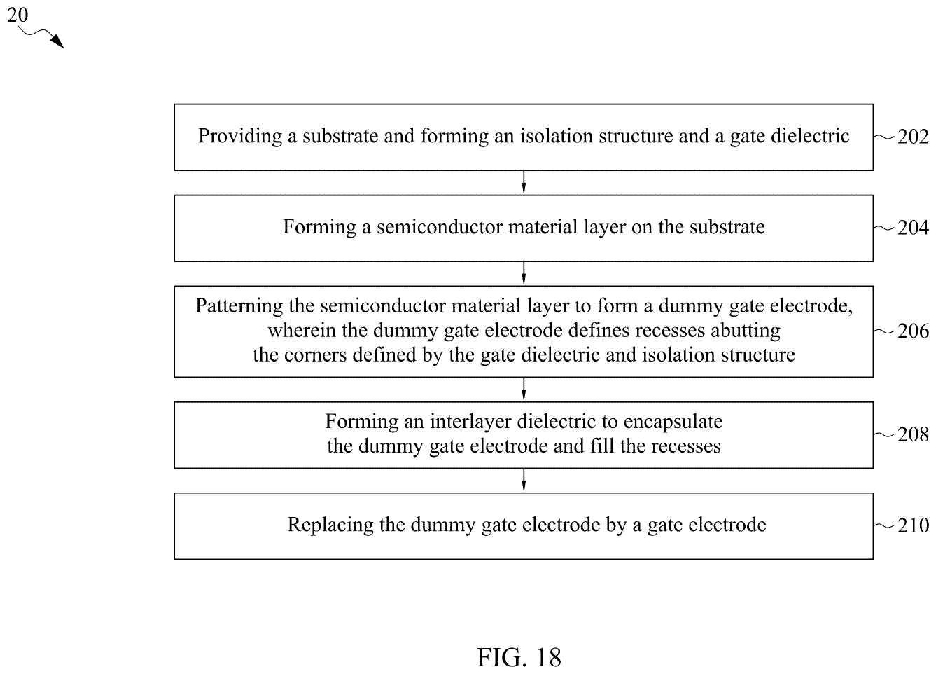

FIG. 18 is a flowchart of a method 20 for manufacturing a semiconductor device according to various aspects of the present disclosure.

The method 20 begins with an operation 202 in which a substrate is provided. An isolation structure is formed within the substrate. A gate dielectric is formed on the substrate. FIGS. 13A to 13C illustrate the stage corresponding to the operation 202.

The method 20 continues with an operation 204 in which a semiconductor material layer is formed to cover the substrate. FIGS. 14A to 14C illustrate the stage corresponding to operation 204.

The method 20 continues with an operation 206 in which the semiconductor material layer is patterned to define a dummy gate electrode. The dummy gate electrode defines recesses abutting the corners defined by the gate dielectric and isolation structure in a top view. S/D regions are formed on opposite sides of the dummy gate electrode. FIGS. 15A to 15C illustrate the stage corresponding to operation 206.

The method 20 continues with an operation 208 in which an ILD is formed to encapsulate the dummy gate electrode and fill the recesses of the dummy gate electrode. FIGS. 16A to 16C illustrate the stage corresponding to operation 208.

The method 20 continues with an operation 210 in which the dummy gate electrode is replaced by a gate electrode. The gate electrode inherits the profile of the dummy gate electrode. FIGS. 17A to 17C illustrate the stage corresponding to operation 210.

The method 20 is merely an example, and is not intended to limit the present disclosure beyond what is explicitly recited in the claims. Additional operations can be provided before, during, and after the method 20, and some operations described can be replaced, eliminated, or reordered for additional embodiments of the method.

Some embodiments of the present disclosure provide a semiconductor device. The semiconductor device includes a substrate, a gate dielectric, an isolation structure, and a gate electrode. The gate dielectric is disposed on the substrate. The isolation structure is within the substrate. The gate dielectric includes a tapered portion abutting the isolation structure. The gate electrode is disposed on the gate dielectric and the isolation structure. The tapered portion of the gate dielectric is exposed by the gate electrode.

Some embodiments of the present disclosure provide a method of manufacturing a semiconductor device. The method includes providing a substrate and forming an isolation structure within the substrate. The method also includes forming a gate dielectric abutting the isolation structure. The isolation structure and the gate dielectric define a corner in a top view. The method further includes forming a gate electrode on the gate dielectric and the isolation structure. In addition, the method includes forming an interlayer dielectric (ILD). The corner is exposed by the gate electrode and covered by the ILD.

Some embodiments of the present disclosure provide a method of manufacturing a semiconductor device. The method includes providing a substrate and forming an isolation structure within the substrate. The method also includes forming a gate dielectric abutting the isolation structure. The isolation structure and the gate dielectric define a first corner and a second corner in a top view. The method further includes forming a dummy gate on the gate dielectric and the isolation structure to cover the first corner and the second corner. In addition, the method includes patterning the dummy gate to expose the first corner. The method further includes replacing the dummy gate by a gate electrode.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a substrate;
a gate dielectric disposed on the substrate;
an isolation structure within the substrate, wherein the gate dielectric comprises a tapered portion abutting the isolation structure; and
a gate electrode disposed on the gate dielectric and the isolation structure,
wherein the tapered portion of the gate dielectric is exposed by the gate electrode.

2. The semiconductor device of claim 1, wherein the isolation structure and the gate dielectric define a first corner at a first side of the gate dielectric, and the first corner is exposed by the gate electrode.

3. The semiconductor device of claim 2, wherein the isolation structure and the gate dielectric define a second corner at a second side, opposite to the first side of the gate dielectric, and the second corner is covered by the gate electrode.

4. The semiconductor device of claim 3, wherein the isolation structure comprises a first portion abutting the first side of the gate dielectric and a second portion abutting the second side of the gate dielectric, and a depth of the first portion of the isolation structure is greater than a depth of the second portion of the isolation structure.

5. The semiconductor device of claim 3, wherein the gate dielectric comprises a first portion abutting the first side of the gate dielectric and a second portion abutting the second side of the gate dielectric, and a thickness of the first portion of the gate dielectric is less than a thickness of the second portion of the gate dielectric.

6. The semiconductor device of claim 2, further comprising:
an interlayer dielectric (ILD) encapsulating the gate electrode, wherein a portion of the ILD is surrounded by the gate electrode.

7. The semiconductor device of claim 6, wherein the portion of the ILD covers the first corner.

8. The semiconductor device of claim 1, wherein the gate electrode defines an indentation recessed from a lateral surface of the gate electrode in a top view.

9. The semiconductor device of claim 8, further comprising:
an interlayer dielectric (ILD) encapsulating the gate electrode, wherein the ILD comprises a protruding portion extending into the indentation of the gate electrode in the top view.

10. The semiconductor device of claim 1, further comprising:
a first source/drain (S/D) region; and
a second S/D region, wherein the gate dielectric has a first side abutting the first S/D region and a second side abutting the S/D region,
and wherein a first percentage of the substrate abutting the first side of the gate dielectric, covered by the gate electrode is less than a second percentage of the substrate, abutting the second side of the gate dielectric, covered by the gate electrode.

11. The semiconductor device of claim 1, wherein the gate electrode has a first side and a second side opposite to the first side, and a length of the first side of the gate electrode is less than that of the second side of the gate electrode.

12. A method of manufacturing a semiconductor device, comprising:
providing a substrate;
forming an isolation structure within the substrate;
forming a gate dielectric abutting the isolation structure, wherein the isolation structure and the gate dielectric define a corner in a top view;
forming a gate electrode on the gate dielectric and the isolation structure; and
forming an interlayer dielectric (ILD),
wherein the corner is exposed by the gate electrode and covered by the ILD.

13. The method of claim 12, further comprising:
forming a dummy gate on the gate dielectric and the isolation structure;
patterning the dummy gate to define a cavity exposing the corner,
forming the ILD to fill the cavity; and
replacing the dummy gate by the gate electrode.

14. The method of claim 13, further comprising:
forming a first source/drain (S/D) region and a second S/D region on opposite sides of the gate dielectric after the cavity of the dummy gate is defined.

15. The method of claim 14, wherein forming the isolation structure comprises:
forming a first region of the isolation structure with a first thickness; and
forming a second region of the isolation structure with a second thickness less than the first thickness,
wherein the cavity abuts the first region of the isolation structure.

16. The method of claim 12, wherein the gate dielectric has a first thickness abutting the corner and a second thickness far from the corner, and the first thickness is less than the second thickness.

17. The method of claim 12, wherein a part of the ILD is surrounded by the gate electrode.

18. A method of manufacturing a semiconductor device, comprising:
providing a substrate;
forming an isolation structure within the substrate;
forming a gate dielectric abutting the isolation structure;
forming a dummy gate on the gate dielectric and the isolation structure;
patterning the dummy gate to form a first portion and a second portion disconnected from the first portion in a cross-sectional view; and
replacing the dummy gate by a gate electrode.

19. The method of claim 18, further comprising:
forming an interlayer dielectric (ILD) between the first portion and the second portion of the dummy gate;
removing the dummy gate; and
forming the gate electrode, wherein the gate electrode has a first portion and a second portion disconnected from the first portion in the cross-sectional view.

20. The method of claim 18, wherein patterning the dummy gate comprises:
removing a portion of the dummy gate to expose a first side of the gate dielectric,
wherein a second side, opposite to the first side, of the gate dielectric is covered by the dummy gate in the cross-sectional view.
